(19) United States
(12) Patent Application Publication
(10) Pub. No.: US 2025/0268087 A1
(43) Pub. Date: Aug. 21, 2025

(54) DISPLAY DEVICE AND OPTICAL DEVICE INCLUDING THE SAME

(71) Applicant: Samsung Display Co., LTD., Yongin-si (KR)

(72) Inventors: Jong Ho SON, Yongin-si (KR); Dae Won KIM, Yongin-si (KR); Tae Ho KIM, Yongin-si (KR); Mi Hwa LEE, Yongin-si (KR); Sung Gyu JANG, Yongin-si (KR)

(21) Appl. No.: 18/910,340

(22) Filed: Oct. 9, 2024

(30) Foreign Application Priority Data
Feb. 19, 2024 (KR) 10-2024-0023406

(51) Int. Cl. H10K 59/80; G02B 27/01; H10K 59/122; H10K 59/38

(52) U.S. Cl. CPC H10K 59/8793; G02B 27/0172; H10K 59/122; H10K 59/38; H10K 59/80515; H10K 59/80518; H10K 59/879; G02B 2027/0178

(57) ABSTRACT

A display device includes: a substrate; a plurality of first electrodes on the substrate; a pixel defining layer defining a plurality of emission areas disposed to correspond to the plurality of first electrodes, respectively; a light emitting layer on the plurality of first electrodes; and a second electrode on the light emitting layer, wherein each of the plurality of emission areas has a circular shape in the plan view, and the plurality of emission areas have the same size in the plan view.

This application claims priority to Korean Patent Application No. 10-2024-0023406 filed on Feb. 19, 2024, and all the benefits accruing therefrom under 35 U.S.C. § 119, the content of which in its entirety is herein incorporated by reference.

### BACKGROUND

### 1. Technical Field

The present disclosure relates to a display device and an optical device, and more particularly, to a display device and an optical device capable of improving light recycling efficiency.

### 2. Description of the Related Art

A head mounted display (“HMD”) is an image display device that is worn on a user's head in the form of glasses or helmets to form a focus at a close distance in front of the user's eyes. The head mounted display may implement virtual reality (“VR”) or augmented reality (“AR”).

The head mounted display magnifies an image displayed on a small display device by using a plurality of lenses, and displays the magnified image. Therefore, the display device applied to the head mounted display is desirable to provide high-resolution images, for example, images with a resolution of 3000 Pixels Per Inch (“PPI”) or higher. To this end, an organic light emitting diode on silicon (“OLEDOS”), which is a high-resolution small organic light emitting display device, is used as the display device applied to the head mounted display. The OLEDOS is an image display device in which an organic light emitting diode (OLED) is disposed on a semiconductor wafer substrate on which a complementary metal oxide semiconductor (“CMOS”) is disposed.

### SUMMARY

Aspects of the present disclosure provide a display device and an optical device capable of improving light recycling efficiency.

According to an embodiment of the disclosure, a display device includes: a substrate; a plurality of first electrodes on the substrate; a pixel defining layer defining a plurality of emission areas disposed to correspond to the plurality of first electrodes, respectively; a light emitting layer on the plurality of first electrodes; and a second electrode on the light emitting layer, wherein each of the plurality of emission areas has a circular shape in a plan view, and the plurality of emission areas have the same size in the plan view.

In an embodiment, the display device may further include a wire grid polarizer on the second electrode.

In an embodiment, the display device may further include a lens layer on the wire grid polarizer.

In an embodiment, the display device may further include a color filter layer between the second electrode and the wire grid polarizer.

In an embodiment, the display device may further include a retardation layer between the second electrode and the wire grid polarizer.

In an embodiment, each of the plurality of first electrodes may have a circular shape in the plan view.

In an embodiment, the plurality of first electrodes may have the same size in the plan view.

In an embodiment, the display device may further include a plurality of reflective electrode layers connected to the plurality of first electrodes, respectively.

In an embodiment, each of the plurality of reflective electrode layers may have a circular shape in the plan view.

In an embodiment, the plurality of reflective electrode layers may have the same size in the plan view.

In an embodiment, the plurality of emission areas may be configured to provide light of different colors.

According to an embodiment of the disclosure, an optical device includes: a display device; and an optical path changing member on the display device, where the display device includes: a substrate; a plurality of first electrodes on the substrate; a pixel defining layer defining a plurality of emission areas disposed to correspond to the plurality of first electrodes, respectively; a light emitting layer on the plurality of first electrodes; and a second electrode on the light emitting layer. Each of the plurality of emission areas has a circular shape in a plan view, and the plurality of emission areas have the same size in the plan view.

In an embodiment, the optical device may further include a wire grid polarizer on the second electrode.

In an embodiment, the optical device may further include a lens layer on the wire grid polarizer.

In an embodiment, the optical device may further include a color filter layer between the second electrode and the wire grid polarizer.

In an embodiment, the optical device may further include a retardation layer between the second electrode and the wire grid polarizer.

In an embodiment, each of the plurality of first electrodes may have a circular shape in the plan view.

In an embodiment, the plurality of first electrodes may have the same size in the plan view.

In an embodiment, the optical device may further include a plurality of reflective electrode layers connected to the plurality of first electrodes, respectively.

In an embodiment, each of the plurality of reflective electrode layers may have a circular shape in the plan view.

In an embodiment, the plurality of reflective electrode layers may have the same size in the plan view.

In an embodiment, the plurality of emission areas may be configured to provide light of different colors.

According to the display device and the optical device of the present disclosure, light recycling efficiency may be improved. Accordingly, the image quality of the display device may be effectively improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view showing a display device according to one embodiment;

FIG. 2 is a layout diagram illustrating an example of the display panel shown in FIG. 1;

FIG. 3 is an equivalent circuit diagram of a sub-pixel according to one embodiment;

FIG. 4 is a layout diagram illustrating an example of a display panel according to one embodiment;

FIG. 5 is a layout diagram showing embodiments of the display area of FIG. 4;

FIG. 6 is a cross-sectional view illustrating an example of the display panel taken along line X-X′ of FIG. 5;

FIG. 7 is a cross-sectional view illustrating another example of the display panel taken along line X-X′ of FIG. 5;

FIG. 8 is a cross-sectional view illustrating still another example of the display panel taken along line X-X′ of FIG. 5;

FIG. 9 is a cross-sectional view illustrating yet another example of the display panel taken along line X-X′ of FIG. 5;

FIG. 10 is a diagram for describing optical paths of main light and reflected light;

FIG. 11 is a diagram showing various shapes of the emission area;

FIG. 12 is a diagram for describing light recycling efficiency according to Chief Ray Angle (“CRA”) for each emission area in FIG. 11;

FIGS. 13A to 13C are diagrams showing light recycling efficiency for each emission area in FIG. 11 according to the ratio of the horizontal and vertical sides of the corresponding emission area;

FIGS. 14A to 14E are diagrams for describing light recycling efficiency based on main light and reflected light;

FIG. 15 is a perspective view illustrating a head mounted display according to one embodiment;

FIG. 16 is an exploded perspective view illustrating an example of the head mounted display of FIG. 15; and

FIG. 17 is a perspective view illustrating a head mounted display according to one embodiment.

### DETAILED DESCRIPTION

Advantages and features of the present disclosure and methods to achieve them will

become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as “first,” “second,” etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various exemplary embodiments of the present disclosure may be combined partially or totally. As will be clearly appreciated by those skilled in the art, technically various interactions and operations are possible. Various exemplary embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, exemplary embodiments of the present disclosure will be described with reference to the accompanying drawings.

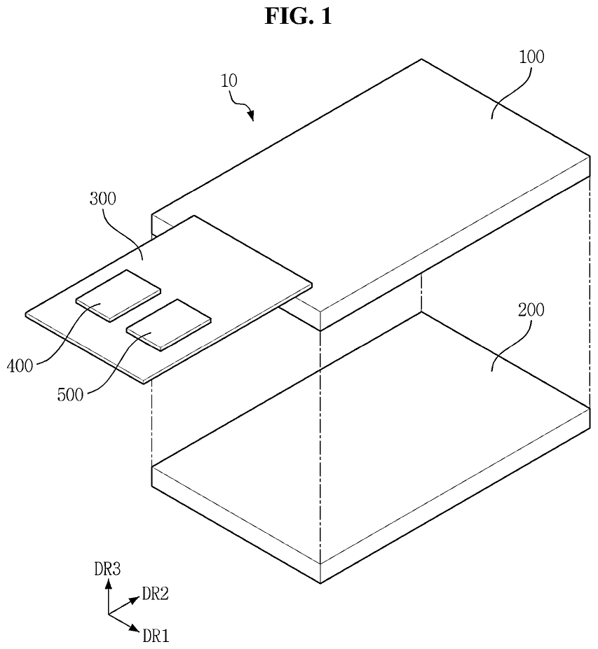

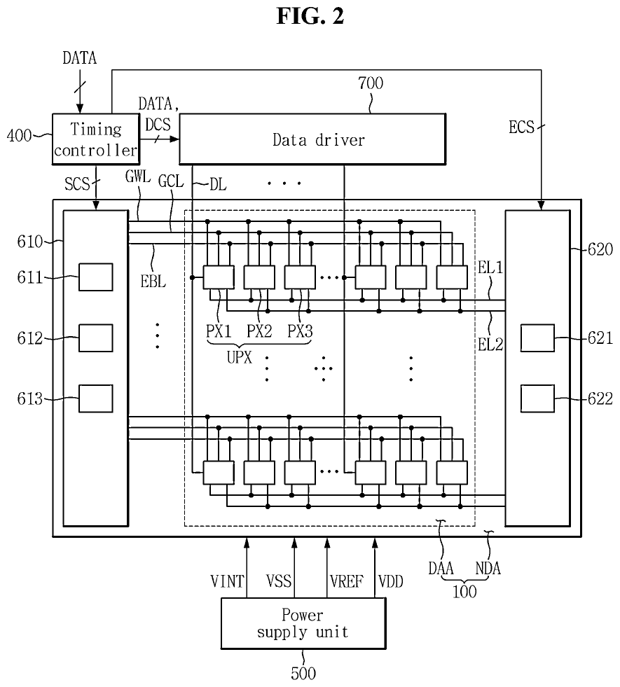

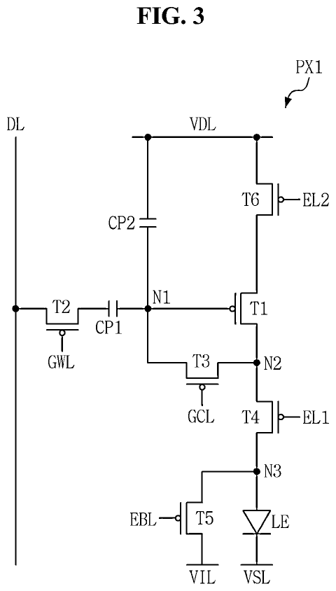

FIG. 1 is an exploded perspective view showing a display device according to one embodiment. FIG. 2 is a layout diagram illustrating an example of the display panel shown in FIG. 1. FIG. 3 is an equivalent circuit diagram of a sub-pixel according to one embodiment.

FIG. 1 is an exploded perspective view showing a display device according to one embodiment. FIG. 2 is a block diagram illustrating a display device according to one embodiment.

Referring to FIGS. 1 and 2, a display device 10 according to one embodiment is a device for displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (“PMP”), a navigation system, an ultra mobile PC (“UMPC”) or the like. For example, the display device 10 according to one embodiment may be applied as a display unit of a television, a laptop, a monitor, a billboard, or an Internet-of-Things (“IoT”) terminal. Alternatively, the display device 10 according to one embodiment may be applied to a smart watch, a watch phone, a head mounted display (HMD) for implementing virtual reality and augmented reality, and the like.

The display device 10 according to one embodiment includes a display panel 100, a heat dissipation layer 200, a circuit board 300, a timing control circuit 400, and a power supply circuit 500.

The display panel 100 may have a planar shape (i.e., shape in a plan view) similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the present specification is not limited thereto.

The display panel 100 includes a display area DAA for displaying an image and a non-display area NDA not for displaying an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

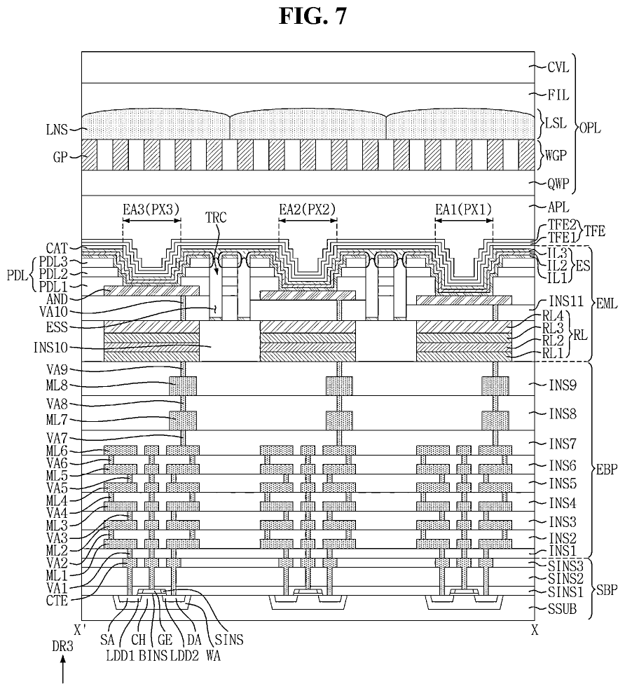

Each of a plurality of unit pixels PX includes a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be disposed on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA includes a scan driver 610, an emission driver 620, and the data driver 700.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the embodiment of the present specification is not limited thereto. For another example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

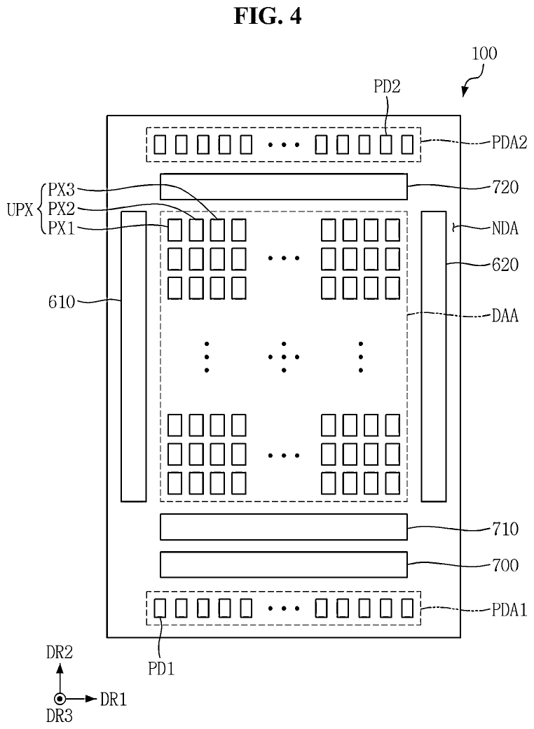

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (“IC”) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on a semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is an equivalent circuit diagram of a sub-pixel according to one embodiment.

Referring to FIG. 3, a first pixel PX1 may be connected to the write scan line GWL, the control scan line GCL, the bias scan line EBL, the first emission control line EL1, the second emission control line EL2, and the data line DL. In addition, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first pixel PX1 includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the present specification is not limited thereto. For another example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor, which controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (“MOSFET”). For example, each of the first to sixth transistors T1 to T6 may be a P-type MOSFET, but the embodiment of the present specification is not limited thereto. In another embodiment, each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first pixel PX1 includes the six transistors T1 to T6 and the two capacitors C1 and C2, it should be noted that the equivalent circuit diagram of the first pixel PX1 is not limited to the example shown in FIG. 3. For example, the number of the transistors and the number of the capacitors of the first pixel PX1 are not limited to the example shown in FIG. 3.

In addition, the equivalent circuit diagram of a second pixel PX2 and the equivalent circuit diagram of third pixel PX3 may be substantially the same as the equivalent circuit diagram of the first pixel PX1 described in conjunction with FIG. 3. Thus, in the present specification, description of the equivalent circuit diagram of the second pixel PX2 and the equivalent circuit diagram of the third pixel PX3 will be omitted.

FIG. 4 is a layout diagram illustrating an example of a display panel according to one embodiment.

Referring to FIG. 4, the display area DAA of the display panel 100 according to one embodiment includes the plurality of pixels PX arranged in a matrix form. The non-display area NDA of the display panel 100 according to one embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the embodiment of the present specification is not limited thereto, and the scan driver 610 and the emission driver 620 may be disposed on both the first side and the second side of the display area DAA in another embodiment. The first pad portion PDA1 may include the plurality of first pads PD1 connected to

pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads, which test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

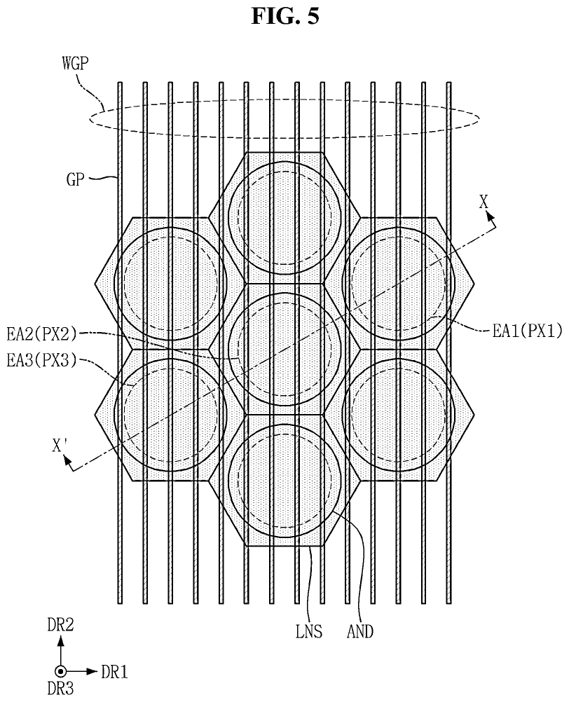

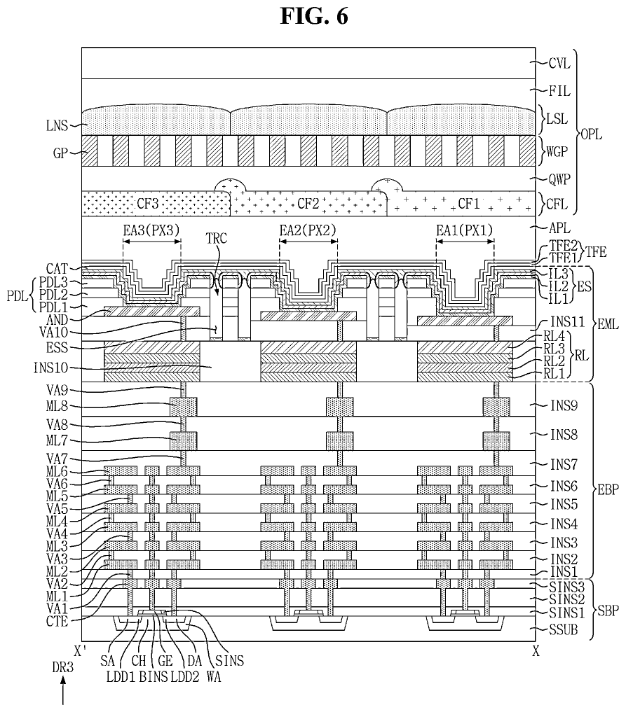

FIG. 5 is a layout diagram showing embodiments of the display area of FIG. 4. FIG. 5 is a plan view. As used herein, the “plan view” is a view in a thickness direction (i.e., third direction DR3) of the substrate SSUB (See FIG. 6).

Referring to FIG. 5, each of the plurality of pixels PX may include a first emission area EA1 as an emission area of the first pixel PX1, a second emission area EA2 as an emission area of the second pixel PX2, and a third emission area EA3 as an emission area of the third pixel PX3.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 380 nanometers (nm) to about 480 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In a plan view, each of the first emission area EA1, the second emission area EA2, and the third emission area EA3 may have a circular shape. For example, in a plan view, the first emission area EA1, the second emission area EA2, and the third emission area EA3 may have the same circular shape.

In a plan view, the size (e.g., the opening area) of the first emission area EA1, the size (e.g., the opening area) of the second emission area EA2, and the size (e.g., the opening area) of the third emission area EA3 may be the same. Here, the size of each of the emission areas EA1, EA2, and EA3 may refer to the area of the emission area based on the size in the first direction DR1 and the size in the second direction DR2.

It is exemplified in FIG. 5 that each of the plurality of pixels PX includes three emission areas EA1, EA2, and EA3, but the embodiment of the present specification is not limited thereto. In another embodiment, each of the plurality of pixels PX may include four emission areas.

In addition, the disposition of the emission areas EA1, EA2, and EA3 of the plurality of pixels PX is not limited to that illustrated in FIG. 5. For example, the emission areas EA1, EA2, and EA3 of the plurality of pixels PX may be disposed in a stripe structure in which the emission areas EA1, EA2, and EA3 are arranged in the first direction DR1, or in a PenTile® structure in which the emission areas are arranged in a diamond pattern.

Each of the pixels PX1, PX2 and PX3 may include an anode electrode AND. For example, each of the first pixel PX1, the second pixel PX2, and the third pixel PX3 may include the anode electrode AND. In a plan view, the anode electrode AND of the first pixel PX1 (hereinafter, referred to as a first anode electrode), the anode electrode AND of the second pixel PX2 (hereinafter, referred to as a second anode electrode), and the anode electrode AND of the third pixel PX1 (hereinafter, referred to as a third anode electrode) may each have a circular shape. For example, the first anode electrode may have the same shape as the first emission area EA1, the second anode electrode may have the same shape as the second emission area EA2, and the third anode electrode may have the same shape as the third emission area EA3. In other words, in a plan view, the first anode electrode, the second anode electrode, and the third anode electrode may have the same circular shape.

In a plan view, the size (e.g., the area) of the first anode electrode, the size (e.g., the area) of the second anode electrode, and the size (e.g., the area) of the third anode electrode may be the same. Here, the size of each anode electrode AND may refer to the area of the anode electrode AND based on the size in the first direction DR1 and the size in the second direction DR2.

Lenses LNS may be disposed on the emission areas EA1, EA2, and EA3, respectively. For example, the lens LNS may be disposed on each of the first emission area EA1, the second emission area EA2, and the third emission area EA3. In a plan view, the lens LNS may have a hexagonal shape.

A wire grid polarizer WGP may be disposed on the emission areas EA1, EA2, and EA3. The wire grid polarizer WGP may include a plurality of grid patterns GP. As shown in FIG. 5, each grid pattern GP may have a rectangular shape extending along the second direction DR2. Further, as shown in FIG. 5, the grid patterns GP may be arranged along the first direction DR1. The grid patterns GP may be disposed to be spaced apart from each other in the first direction DR1. The wire grid polarizer WGP may contain at least one of aluminum (Al), silver (Ag), or gold (Au). For example, each of the grid patterns GP may be made of a material containing at least one of aluminum (Al), silver (Ag), or gold (Au).

FIG. 6 is a cross-sectional view illustrating an example of the display panel 100 taken along line X-X′ of FIG. 5.

Referring to FIG. 6, the display panel 100 may include a semiconductor backplane SBP, a light emitting element backplane EBP, a display element layer EML, an encapsulation layer TFE, and an optical layer OPL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region

CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but the embodiment of the present specification is not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but the embodiment of the present specification is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the embodiment of the present specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of insulating layers INS1 to INS9. In addition, the light emitting element backplane EBP includes a plurality of insulating layers INS1 to INS11 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first pixel PX1 shown in FIG. 4. For example, the first to sixth transistors T1 to T6 are merely formed on the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

The first insulating layer INS1 may be disposed on the semiconductor backplane SBP. Each of the first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

The second insulating layer INS2 may be disposed on the first insulating layer INS1 and the first conductive layers ML1. Each of the second vias VA2 may penetrate the second insulating layer INS2 and be connected to the exposed first conductive layer ML1. Each of the second conductive layers ML2 may be disposed on the second insulating layer INS2 and may be connected to the second via VA2.

The third insulating layer INS3 may be disposed on the second insulating layer INS2 and the second conductive layers ML2. Each of the third vias VA3 may penetrate the third insulating layer INS3 and be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of the fourth vias VA4 may penetrate the fourth insulating layer INS4 and be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of the sixth vias VA6 may penetrate the sixth insulating layer INS6 and be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOx)-based inorganic layer, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å; the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating layer INS9 may be disposed on the eighth insulating layer INS8 and the eighth conductive layer ML8. The ninth insulating layer INS9 may be formed of a silicon oxide (SiOx)-based inorganic layer, but the embodiment of the present specification is not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EML may be disposed on the light emitting element backplane EBP. The display element layer EML may include light emitting elements LE each including a reflective electrode layer RL, tenth and eleventh insulating layers INS10 and INS11, a tenth via VA10, the anode electrode AND, a light emitting stack ES, and a cathode electrode CAT; a pixel defining layer PDL; and a plurality of trenches TRC.

The reflective electrode layer RL may be disposed on the ninth insulating layer INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 6.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be disposed on the third reflective electrodes RL3, respectively. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode, which substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å.

A tenth insulating layer INS10 may be disposed on the ninth insulating layer INS9. The tenth insulating layer INS10 may be disposed between the reflective electrode layers RL adjacent to each other in a horizontal direction. The tenth insulating layer INS10 may be disposed on the reflective electrode layer RL in the third pixel PX3. The tenth insulating layer INS10 may be formed of a silicon oxide (SiOx)-based inorganic layer, but the embodiment of the present specification is not limited thereto.

An eleventh insulating layer INS11 may be disposed on the tenth insulating layer INS10 and the reflective electrode layer RL. The eleventh insulating layer INS11 may be formed of a silicon oxide (SiOx)-based inorganic layer, but the embodiment of the present specification is not limited thereto. In another embodiment, the tenth insulating layer INS10 and the eleventh insulating layer INS11 may be an optical auxiliary layer through which light reflected by the reflective electrode layer RL passes, among light emitted from the light emitting elements LE.

In order to match the resonance distance of the light emitted from the light emitting elements LE in at least one of the first pixel PX1, the second pixel PX2, or the third pixel PX3, the tenth insulating layer INS10 and the eleventh insulating layer INS11 may not be disposed under the anode electrode AND of the first pixel PX1. The anode electrode AND of the first pixel PX1 may be directly disposed on the reflective electrode layer RL. The eleventh insulating layer INS11 may be disposed under the anode electrode AND of the second pixel PX2. The tenth insulating layer INS10 and the eleventh insulating layer INS11 may be disposed under the anode electrode AND of the third pixel PX3.

In summary, the distance between the anode electrode AND and the reflective electrode layer RL may be different in the first pixel PX1, the second pixel PX2, and the third pixel PX3. In order to adjust the distance from the reflective electrode layer RL to the cathode electrode CAT according to the main wavelength of the light emitted from each of the first pixel PX1, the second pixel PX2, and the third pixel PX3, the presence or absence of the tenth insulating layer INS10 and the eleventh insulating layer INS11 may be set in each of the first pixel PX1, the second pixel PX2, and the third pixel PX3. For example, it is illustrated in FIG. 6 that the distance between the anode electrode AND and the reflective electrode layer RL in the third pixel PX3 is larger than the distance between the anode electrode AND and the reflective electrode layer RL in the second pixel PX2 and the distance between the anode electrode AND and the reflective electrode layer RL in the first pixel PX1, and the distance between the anode electrode AND and the reflective electrode layer RL in the second pixel PX2 is larger than the distance between the anode electrode AND and the reflective electrode layer RL in the first pixel PX1, but the specification of the present disclosure is not limited thereto.

According to one embodiment, in a plan view, the reflective electrode layer RL disposed to overlap the first emission area EA1 of the first pixel PX1 (hereinafter referred to as a first reflective electrode layer), the reflective electrode layer RL disposed to overlap the second emission area EA2 of the second pixel PX2 (hereinafter referred to as a second reflective electrode layer), and the reflective electrode layer RL disposed to overlap the third emission area EA3 of the third pixel PX3 (hereinafter referred to as a third reflective electrode layer) may each have a circular shape. For example, the first reflective electrode layer may have the same shape as the first emission area EA1 (or the first anode electrode), the second reflective electrode layer may have the same shape as the second emission area EA2 (or the second anode electrode), and the third reflective electrode layer may have the same shape as the third emission area EA3 (or the third anode electrode). In other words, in a plan view, the first reflective electrode layer, the second reflective electrode layer, and the third reflective electrode layer may have the same circular shape.

In a plan view, the size (e.g., the area) of the first reflective electrode layer, the size (e.g., the area) of the second reflective electrode layer, and the size (e.g., the area) of the third reflective electrode layer may be the same. Here, the size of each reflective electrode layer RL may refer to the area of the reflective electrode layer RL based on the size in the first direction DR1 and the size in the second direction DR2.

In addition, although the tenth insulating layer INS10 and the eleventh insulating layer INS11 are illustrated in the embodiment of the present specification, a twelfth insulating layer disposed under the anode electrode AND of the first pixel PX1 may be added. In this case, the eleventh insulating layer INS11 and the twelfth insulating layer INS12 may be disposed under the anode electrode AND of the second pixel PX2, and the tenth insulating layer INS10, the eleventh insulating layer INS11, and the twelfth insulating layer INS12 may be disposed under the anode electrode AND of the third pixel PX3.

Each of the tenth vias VA10 may penetrate the tenth insulating layer INS10 and/or the eleventh insulating layer INS11 in the second pixel PX2 and the third pixel PX3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second pixel PX2 may be smaller than the thickness of the tenth via VA10 in the third pixel PX3.

The anode electrode AND of each of the light emitting elements LE may be disposed on the tenth insulating layer INS10 and connected to the tenth via VA10. The anode electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The anode electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the anode electrode AND of each of the light emitting elements LE may be titanium nitride (TiN).

The pixel defining layer PDL may be disposed on a part of the anode electrode AND of each of the light emitting elements LE. The pixel defining layer PDL may cover the edge of the anode electrode AND of each of the light emitting elements LE. The pixel defining layer PDL may serve to partition the first emission areas EA1, the second emission areas EA2, and the third emission areas EA3.

The first emission area EA1 may be defined as an area in which the anode electrode AND, the light emitting stack ES, and the cathode electrode CAT are sequentially stacked in the first pixel PX1 to emit light. The second emission area EA2 may be defined as an area in which the anode electrode AND, the light emitting stack ES, and the cathode electrode CAT are sequentially stacked in the second pixel PX2 to emit light. The third emission area EA3 may be defined as an area in which the anode electrode AND, the light emitting stack

ES, and the cathode electrode CAT are sequentially stacked in the third pixel PX3 to emit light.

The pixel defining layer PDL may include first to third pixel defining layers PDL1, PDL2, and PDL3. The first pixel defining layer PDL1 may be disposed on the edge of the anode electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOx)-based inorganic layer, but the embodiment of the present specification is not limited thereto. In another embodiment, the first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Furthermore, each of the plurality of trenches TRC may penetrate the eleventh insulating layer INS11. The tenth insulating layer INS10 may be partially recessed at each of the plurality of trenches TRC.

At least one trench TRC may be disposed between adjacent pixels PX1, PX2, and PX3. Although FIG. 6 illustrates that two trenches TRC are disposed between adjacent pixels PX1, PX2, and PX3, the embodiment of the present specification is not limited thereto.

The light emitting stack ES may include a plurality of intermediate layers. FIG. 6 illustrates that the light emitting stack ES has a three-tandem structure including a first stack layer IL1, a second stack layer IL2, and a third stack layer IL3, but the embodiment of the present specification is not limited thereto. For another example, the light emitting stack ES may have a two-tandem structure including two intermediate layers.

In the three-tandem structure, the light emitting stack ES may have a tandem structure including a plurality of stack layers IL1, IL2, and IL3, which emit different lights. For example, the light emitting stack ES may include the first stack layer IL1, which emits light of the first color, the second stack layer IL2, which emits light of the second color, and the third stack layer IL3, which emits light of the third color. The first stack layer IL1, the second stack layer IL2, and the third stack layer IL3 may be sequentially stacked.

The first stack layer IL1 may have a structure in which a first hole transport layer, a first organic light emitting layer, which emits light of the first color, and a first electron transport layer are sequentially stacked. The second stack layer IL2 may have a structure in which a second hole transport layer, a second organic light emitting layer, which emits light of the second color, and a second electron transport layer are sequentially stacked. The third stack layer IL3 may have a structure in which a third hole transport layer, a third organic light emitting layer, which emits light of the third color, and a third electron transport layer are sequentially stacked. In this case, the light emitting stack may emit white light in which the light of the first color (e.g., red light) from the first organic light emitting layer, the light of the second color (e.g., green light) from the second organic light emitting layer, and the light of the third color (e.g., blue light) from the third organic light emitting layer are mixed. Accordingly, the white light may be emitted from each of the first emission area EA1, the second emission area EA2, and the third emission area EA3. Here, the white light having passed through the first emission area EA1 may be incident on a first color filter CF1, the white light having passed through the second emission area EA2 may be incident on a second color filter CF2, and the white light having passed through the third emission area EA3 may be incident on a third color filter CF3.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer, which supplies electrons to the first stack layer IL1 and a P-type charge generation layer, which supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer, which supplies electrons to the second stack layer IL2 and a P-type charge generation layer, which supplies holes to the third stack layer IL3.

The first stack layer IL1 may be disposed on the anode electrodes AND and the pixel defining layer PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining layer PDL.

The number of the stack layers IL1, IL2, and IL3, which emit different lights is not limited to that shown in FIG. 6. For example, the light emitting stack ES may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 6 illustrates that the first to third stack layers IL1, IL2, and IL3 are all disposed in the first emission area EA1, the second emission area EA2, and the third emission area EA3, but the embodiment of the present specification is not limited thereto. For another example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The cathode electrode CAT may be disposed on the third stack layer IL3. The cathode electrode CAT may be disposed on the third stack layer IL3 in each of the plurality of trenches TRC. The cathode electrode CAT may be formed of a transparent conductive material (“TCO”) such as Indium Tin Oxide (“ITO”) or Indium Zinc Oxide (“IZO”), which can transmit light or a semi-transmissive conductive material such as magnesium (Mg), silver (Ag), or an alloy of Mg and Ag. When the cathode electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic layer TFE1 and TFE2 to prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the cathode electrode CAT. The first encapsulation inorganic layer TFE1 may be formed as a multilayer in which one or more inorganic layers selected from silicon nitride (SiNx), silicon oxy nitride (SiON), and silicon oxide (SiOx) are alternately stacked. The first encapsulation inorganic layer TFE1 may be formed by a chemical vapor deposition (“CVD”) process.

The second encapsulation inorganic layer TFE2 may be disposed on the first encapsulation inorganic layer TFE1. The second encapsulation inorganic layer TFE2 may be formed of titanium oxide (TiOx) or aluminum oxide (AlOx), but an embodiment of the present specification is not limited thereto. In another embodiment, the second encapsulation inorganic layer TFE2 may be formed by an atomic layer deposition (“ALD”) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include a color filter layer CFL, a lens layer LSL, a filling layer FIL, a cover layer CVL, a retardation layer QWP, and the wire grid polarizer WGP.

The color filter layer CFL may include the plurality of color filters CF1, CF2, and CF3. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 (e.g., red light emission area) of the first pixel PX1 in a plan view. The first color filter CF1 may transmit light of the first color, e.g., light of a red wavelength band. The red wavelength band may be approximately 600 nm to 750 nm. Thus, the first color filter CF1 may transmit light of the first color among light emitted from the first emission area EA1.

The second color filter CF2 may overlap the second emission area EA2 (e.g., green light emission area) of the second pixel PX2 in a plan view. The second color filter CF2 may transmit light of the second color, e.g., light of a green wavelength band. The green wavelength band may be approximately 480 nm to 560 nm. Thus, the second color filter CF2 may transmit light of the second color among light emitted from the second emission area EA2.

The third color filter CF3 may overlap the third emission area EA3 (e.g., blue light emission area) of the third pixel PX3 in a plan view. The third color filter CF3 may transmit light of the third color, e.g., light of a blue wavelength band. The blue wavelength band may be approximately 370 nm to 460 nm. Thus, the first color filter CF1 may transmit light of the first color among light emitted from the first emission area EA1.

The retardation layer QWP (or retardation plate, or retardation film) may be disposed on the color filter layer CFL. For example, the retardation layer QWP may be disposed on the first color filter CF1, the second color filter CF2, and the third color filter CF3. The retardation layer QWP may be a λ/4 plate (quarter-wave plate), but the embodiment of the present specification is not limited thereto. In another embodiment, the stepped portion of the color filter layer CFL may be flattened by the retardation layer.

The wire grid polarizer WGP may be disposed on the retardation layer QWP. The wire grid polarizer WGP and the retardation layer QWP may constitute a polarization member. For example, the polarization member according to one embodiment may include the retardation layer QWP and the wire grid polarizer WGP. The wire grid polarizer WGP may include the plurality of grid patterns GP as stated above.

The wire grid polarizer WGP may transmit light of a specific polarization direction while reflecting light of another polarization direction to recycle it. This wire grid polarizer WGP is useful as a reflective polarizer because it exhibits higher polarization separation performance than other polarizers. For example, the wire grid polarizer WGP is a device, which creates polarization using a conductive wire grid, and may have a structure in which a plurality of wires made of a conductive material are periodically arranged in parallel to each other in a nano size on the retardation layer QWP to form the grid patterns GP. In the wire grid polarizer WGP including the plurality of grid patterns GP, if the period of the grid pattern GP is less than the wavelength of the incident light, diffraction of the incident light does not occur. Thus, the wire grid polarizer WGP may transmit, among the incident light, a component having a vibration direction orthogonal to the conductive grid pattern GP, such as transverse magnetic (“TM”) polarization (e.g., a P wave), while reflecting a component having a vibration direction parallel to the grid pattern GP, such as transverse electric (“TE”) polarization (e.g., a S wave). In other words, when the arrangement period of the grid pattern GP is shorter than the wavelength of the electromagnetic wave incident on the wire grid polarizer WGP, the wire grid polarizer WGP may reflect a polarization component (e.g., S wave) parallel to the grid pattern GP, while transmitting a polarization component (e.g., P wave) orthogonal to the grid pattern GP. Since the wire grid polarizer WGP uses the grid pattern GP made of metal, light reflection efficiency thereof is very high. Thus, as the reflected light can be re-reflected, the light can be recycled to make all lights into one polarized light.

The lens layer LSL may be disposed on the wire grid polarizer WGP. The lens layer LSL may include the plurality of lenses LNS. The plurality of lenses LNS may be disposed on the wire grid polarizer WGP to overlap the first color filter CF1, the second color filter CF2, and the third color filter CF3 in a plan view, respectively. Each of the plurality of lenses LNS may be a structure for increasing a ratio of light directed to the front of the display device 10. Each of the plurality of lenses LNS may have a cross-sectional shape, which is convex in an upward direction.

The filling layer FIL may be disposed on the lens layer LSL. For example, the filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be disposed on the filling layer FIL. The cover layer CVL may be a glass substrate or a polymer resin. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

FIG. 7 is a cross-sectional view illustrating another example of the display panel 100 taken along line X-X′ of FIG. 5.

The display device of FIG. 7 differs from the display device of FIG. 6 in that it does not include the color filter layer CFL described above. The following description will mainly focus on this difference. For example, the display panel 100 of FIG. 6 described above may be a “white-OLED” type display panel in which the light emitting stacks ES of the pixels PX1, PX2, and PX3 included in the unit pixel UPX all provide white light, whereas the display panel 100 of FIG. 7 to be described later may be an “RGB-OLED” type display panel in which the light emitting stacks ES of the pixels PX1, PX2, and PX3 included in the unit pixel UPX provide red light, green light, and blue light, respectively.

As shown in FIG. 7, since the display panel 100 does not include the color filter layer CFL, the organic layer APL and the retardation layer QWP may be in contact with each other.

According to one embodiment, the light emitting stack ES of FIG. 7 may provide light of different colors for each pixel. For example, the light emitting stack ES of the first pixel PX1 may include a red organic light emitting layer, which provides red light, the light emitting stack ES of the second pixel PX2 may include a green organic light emitting layer, which provides green light, and the light emitting stack ES of the third pixel PX3 may include a blue organic light emitting layer, which provides blue light. In other words, the light emitting stack ES may include the red organic light emitting layer described above in the first emission area EA1 of the first pixel PX1, the green organic light emitting layer described above in the second emission area EA2 of the second pixel PX2, and the blue organic light emitting layer described above in the third emission area EA3 of the third pixel PX3. Accordingly, the first pixel PX1 may provide red light generated by the red organic light emitting layer, the second pixel PX2 may provide green light generated by the green organic light emitting layer, and the third pixel PX3 may provide blue light generated by the blue organic light emitting layer.

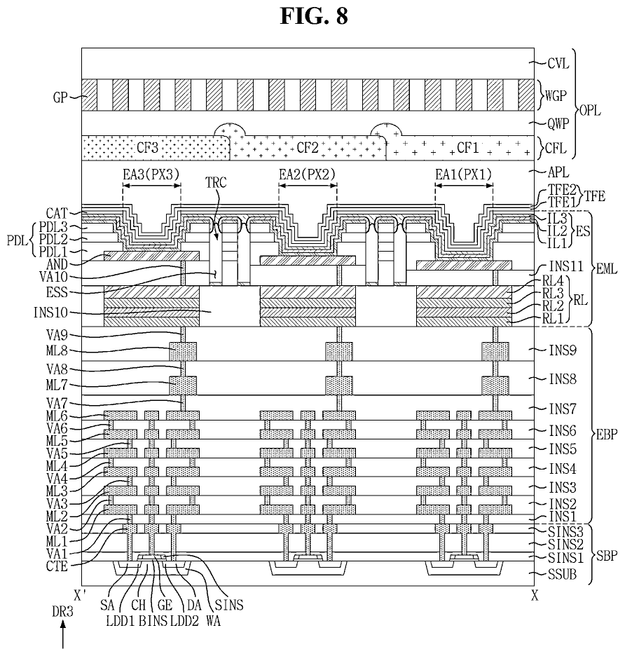

FIG. 8 is a cross-sectional view illustrating still another example of the display panel 100 taken along line X-X′ of FIG. 5.

The display device of FIG. 8 differs from the display device of FIG. 6 in that it does not include the lens layer LSL described above. The following description will mainly focus on this difference.

As shown in FIG. 8, since the display panel 100 does not include the lens layer LSL described above, the wire grid polarizer WGP and the cover layer CVL may be in contact with each other.

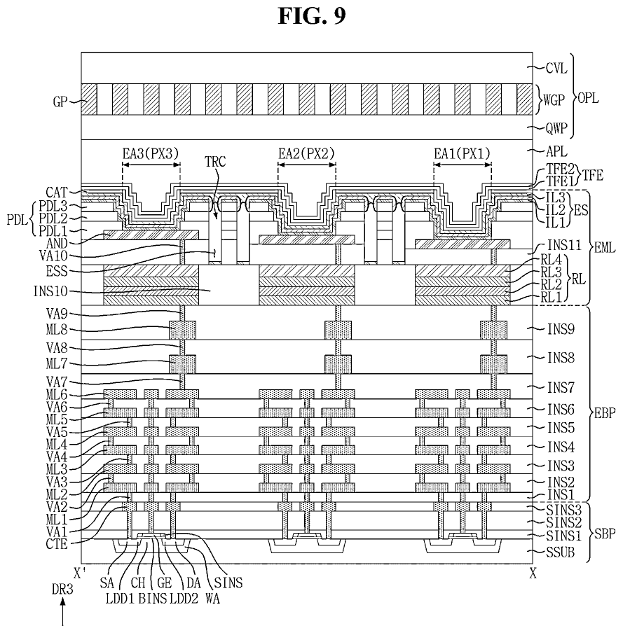

FIG. 9 is a cross-sectional view illustrating yet another example of the display panel 100 taken along line X-X′ of FIG. 5.

The display device of FIG. 9 differs from the display device of FIG. 7 in that it does not include the lens layer LSL described above. The following description will mainly focus on this difference.

As shown in FIG. 9, since the display panel 100 does not include the lens layer LSL described above, the wire grid polarizer WGP and the cover layer CVL may be in contact with each other.

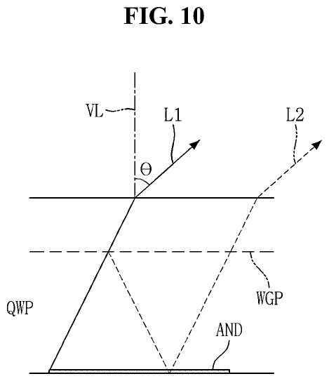

FIG. 10 is a diagram for describing optical paths of main light and reflected light.

Light L1 (hereinafter referred to as main light) emitted from the light emitting element may pass through the wire grid polarizer WGP and be emitted to the outside.

Meanwhile, the light having been reflected from and without passing through the wire grid polarizer WGP is reflected from the anode electrode AND after reaching the anode electrode AND through the retardation layer QWP, and this reflected light L2 passes through the retardation layer QWP again to be incident on the wire grid polarizer WGP. At this time, as the reflected light L2 passes through the retardation layer QWP twice, its polarization direction is changed, so it can be emitted to the outside through the wire grid polarizer WGP. Accordingly, the reflected light L2 can be recycled. In this way, since the reflected light L2 can be recycled by the wire grid polarizer WGP, the light efficiency of the display device can be effectively improved.

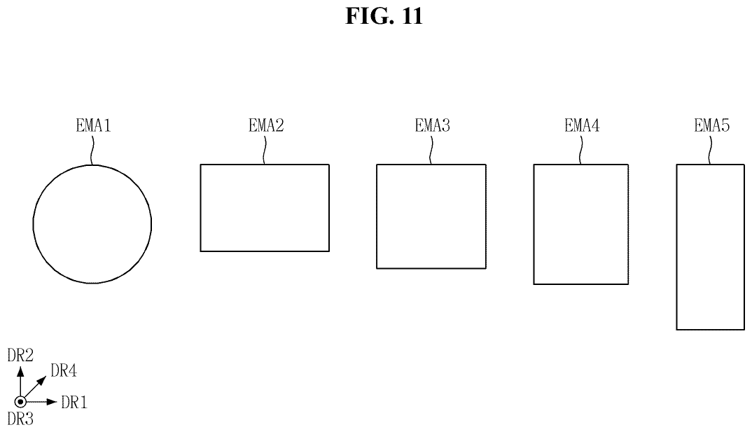

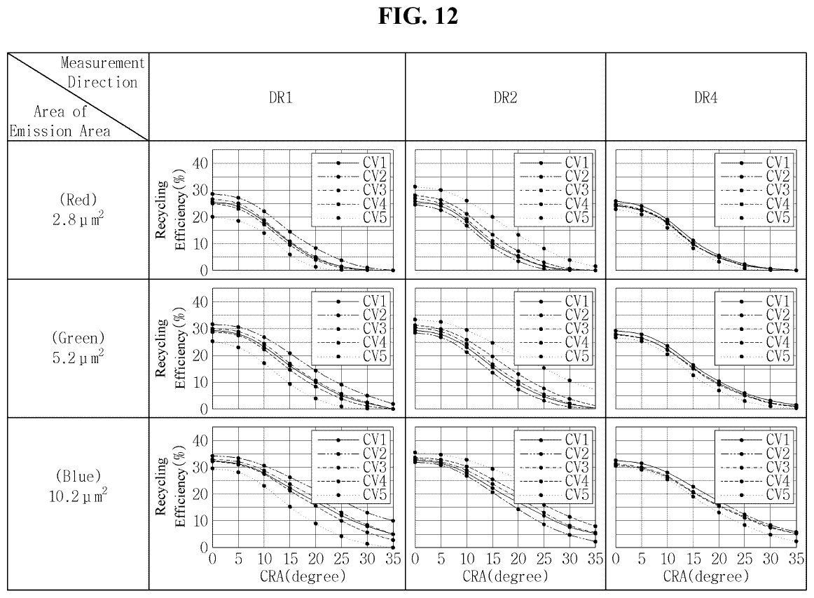

FIG. 11 is a diagram showing various shapes of the emission area, and FIG. 12 is a diagram for describing light recycling efficiency according to Chief Ray Angle (CRA) for each emission area in FIG. 11.

FIG. 11 illustrates a circular emission area EMA1 (hereinafter referred to as a first emission area EMA1), a rectangular emission area EMA2 (hereinafter referred to as a second emission area EMA2) with a ratio of 1:0.7, a square-shaped emission area EMA3 (hereinafter referred to as a third emission area EMA3) with a ratio of 1:1, a rectangular emission area EMA4 (hereinafter referred to as a fourth emission area EMA4) with a ratio of 1:1.3, and a rectangular emission area EMA5 (hereinafter referred to as a fifth emission area EMA5) with a ratio of 1:2.5. Here, the ratio refers to the ratio of the horizontal side to the vertical side of the rectangular emission area in FIG. 11. Meanwhile, the size (e.g., the opening area) of the first emission area EMA1, the size (e.g., the opening area) of the second emission area EMA2, the size (e.g., the opening area) of the third emission area EMA3, the size (e.g., the opening area) of the fourth emission area EMA4, and the size (e.g., the opening area) of the fifth emission area EMA5 in FIG. 11 may be the same.

In FIG. 12, a first curve CV1 is a curve indicating the light recycling efficiency according to the CRA in the first emission area EMA1, a second curve CV2 is a curve indicating the light recycling efficiency according to the CRA in the second emission area EMA2, a third curve CV3 is a curve indicating the light recycling efficiency according to the CRA in the third emission area EMA3, a fourth curve CV4 is a curve indicating the light recycling efficiency according to the CRA in the fourth emission area EMA4, and a fifth curve CV5 is a curve indicating the light recycling efficiency according to the CRA in the fifth emission area EMA5.

As shown in FIG. 10 described above, the CRA may refer to an angle θ between an imaginary line VL perpendicular to the display surface of the display panel 100 and the main light L1 emitted from the display surface. In FIG. 12, the X coordinate represents a CRA value for each of arbitrary points (e.g., eight points) between the center of the display surface of the display panel and one edge thereof. For example, the numerical value 0 in the X coordinate means that the CRA at the center of the display surface is 0 degree, and the numerical value 35 in the X coordinate means that the CRA at one edge of the display surface is 35 degrees. The CRA tends to increase as it goes from the center of the display surface toward one edge thereof.

In FIG. 12, the Y coordinate represents light recycling efficiency.

In FIG. 12, a measurement direction may include the first direction DR1 (e.g., a left-right direction), the second direction DR2 (e.g., an up-down direction), and a fourth direction DR4 (e.g., a diagonal direction). Here, the fourth direction DR4 may be a diagonal direction located between the first direction DR1 and the second direction DR2. The measurement direction may be that of, for example, the CRA.

In FIG. 12, the numerical values 2.8 square micrometers (μm²), 5.2 μm², and 10.2 μm² mean the area of the emission area in a plan view, respectively. Here, the emission area of 2.8 μm² may refer to the area when each emission area is a red light emission area, which emits red light, the emission area of 5.2 μm² may refer to the area when each emission area is a green light emission area, which emits green light, and the emission area of 10.2 μm² may refer to the area when each emission area is a blue light emission area, which emits blue light.

As can be seen from FIG. 12, the first curve CV1 for the first emission area EMA1 may have substantially the same shape regardless of the measurement direction. For example, when the area of the first emission area EMA1 is 2.8 μm², the first curve CV1 based on the first direction DR1, the first curve CV1 based on the second direction DR2, and the first curve CV1 based on the fourth direction DR4 may have almost the same shape. In other words, when the emission area has a circular shape, the light recycling efficiency for each CRA in the first direction DR1, the light recycling efficiency for each CRA in the second direction DR2, and the light recycling efficiency for each CRA in the fourth direction DR4 are found to be almost the same. Thus, when the emission area has a circular shape, the luminance of light in the first direction DR1, the second direction DR2, and the fourth direction DR4 may be maintained almost constant. Accordingly, light of approximately the same luminance can be emitted regardless of the azimuth angle on the display surface (i.e., uniform regardless of the azimuth angle), so that the image quality of the display device can be effectively improved.

Meanwhile, it can be seen from FIG. 12 that the second curve CV2 for the second emission area EMA2, the third curve CV3 for the third emission area EMA3, the fourth curve CV4 for the fourth emission area EMA4, and the fifth curve CV5 for the fifth emission area EMA5 have large deviations depending on the measurement directions DR1, DR2, and DR4.

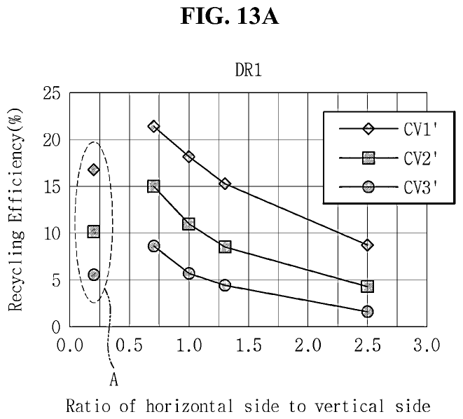

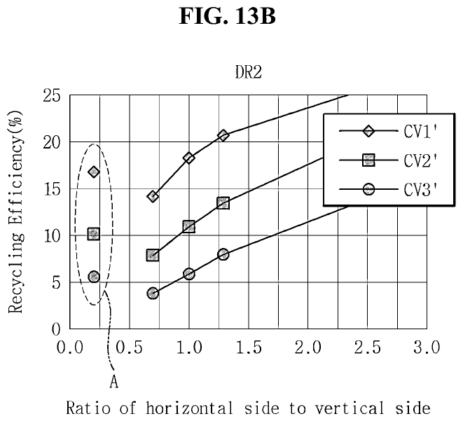

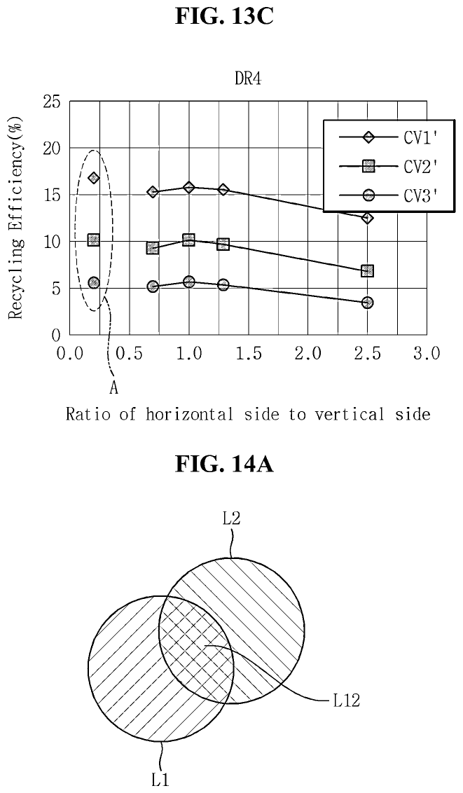

FIGS. 13A to 13C are diagrams showing light recycling efficiency for each emission area in FIG. 11 according to the ratio of the horizontal and vertical sides of the corresponding emission area.

FIG. 13A is a diagram showing the light recycling efficiency for each emission area when the CRA is measured in the first direction DR1, FIG. 13B is a diagram showing the light recycling efficiency for each emission area when the CRA is measured in the second direction DR2, and FIG. 13C is a diagram showing the light recycling efficiency for each emission area when the CRA is measured in the fourth direction DR4.

In FIGS. 13A to 13C, the X coordinate represents the ratio of the horizontal side to the vertical side of the rectangular emission area, and the Y coordinate represents the light recycling efficiency.

In FIGS. 13A to 13C, a first curve CV1′ represents the light recycling efficiency according to the ratio of the horizontal side to the vertical side of the rectangular emission area when the emission area has an area of 10.2 μm², a second curve CV2′ represents the light recycling efficiency according to the ratio of the horizontal side to the vertical side of the rectangular emission area when the emission area has an area of 5.2 μm², and a third curve CV3′ represents the light recycling efficiency according to the ratio of the horizontal side to the vertical side of the rectangular emission area when the emission area has an area of 2.8 μm².

The dots in region A in FIGS. 13A to 13C represent light recycling efficiency for a circular emission area (e.g., EMA1).

As shown in FIGS. 13A to 13C, the circular emission area may have light recycling efficiency of approximately the same level regardless of the measurement direction.

Meanwhile, referring to FIGS. 13A to 13C, the curves in the rectangular emission areas (e.g., the curves disposed in the regions other than the region A in FIGS. 13A to 13C) are found to have large deviations depending on the measurement direction.

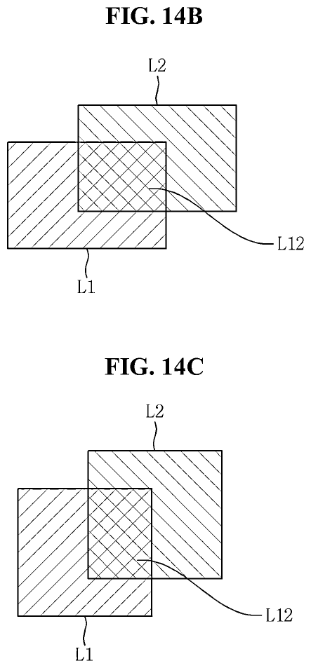

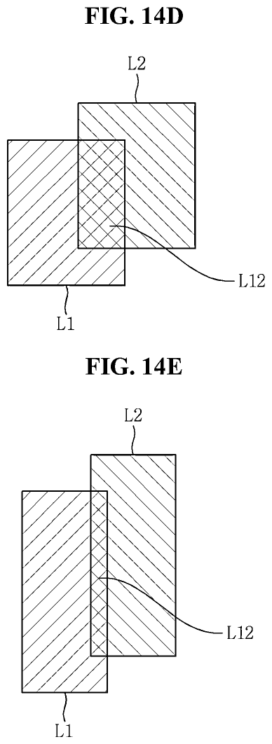

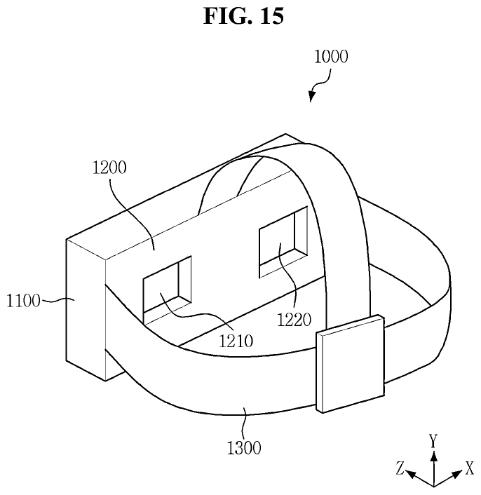

FIGS. 14A to 14E are diagrams for describing light recycling efficiency based on main light and reflected light.

FIG. 14A may be a diagram showing the main light L1 and the reflected light L2 (e.g., recycled light) in the first emission area EMA1 of FIG. 11 described above.

FIG. 14B may be a diagram showing the main light L1 and the reflected light L2 (e.g., recycled light) in the second emission area EMA2 of FIG. 11 described above.

FIG. 14C may be a diagram showing the main light L1 and the reflected light L2 (e.g., recycled light) in the third emission area EMA3 of FIG. 11 described above.

FIG. 14D may be a diagram showing the main light L1 and the reflected light L2 (e.g., recycled light) in the fourth emission area EMA4 of FIG. 11 described above.

FIG. 14E may be a diagram showing the main light L1 and the reflected light L2 (e.g., recycled light) in the fifth emission area EMA5 of FIG. 11 described above.

The larger an overlap area L12 between the main light L1 and the reflected light L2 is, the higher the light recycling efficiency may be. As shown in FIGS. 14A to 14E, the overlap area L12 between the main light L1 and the reflected light L2 from the first emission area EMA1 having a circular shape is the largest. Therefore, it is proved that the light recycling efficiency is high when the emission area has a circular shape.

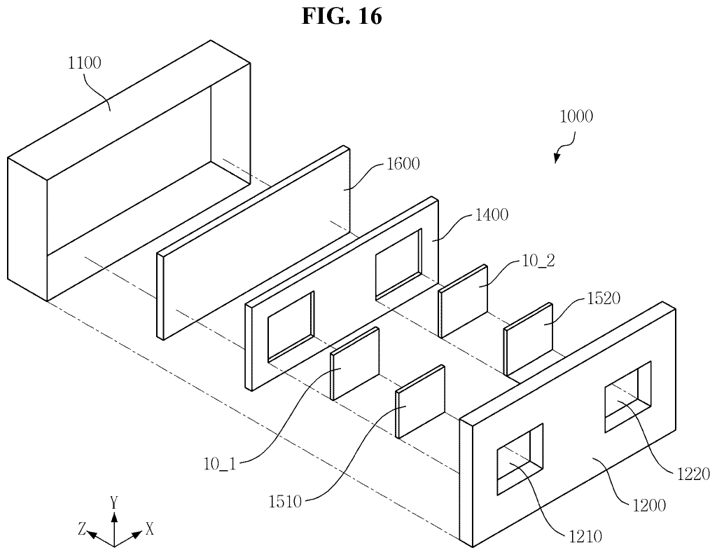

FIG. 15 is a perspective view illustrating a head mounted display according to one embodiment. FIG. 16 is an exploded perspective view illustrating an example of the head mounted display of FIG. 15.

Referring to FIGS. 15 and 16, a head mounted display 1000 according to one embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 15 and 16 illustrate that the first eyepiece 1210 and the second eyepiece 1220 are disposed separately, but the embodiment of the present specification is not limited thereto. In another embodiment, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

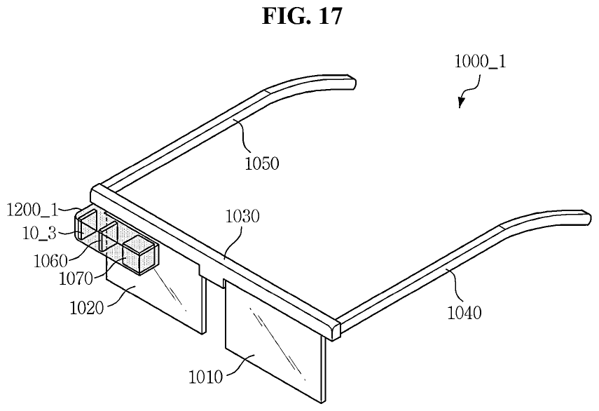

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the head mounted display 1000 may be provided with, as shown in FIG. 17, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (“HDMI”) terminal, and the wireless communication module may be a 5G communication module, a 4G communication module, a Wi-Fi module, or a Bluetooth module.

FIG. 17 is a perspective view illustrating a head mounted display according to one embodiment.

Referring to FIG. 17, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 17 illustrates that the display device housing 1200_1 is disposed at the right end of the support frame 1030, but the embodiment of the present specification is not limited thereto. For another example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate;
a plurality of first electrodes on the substrate;
a pixel defining layer defining a plurality of emission areas disposed to correspond to the plurality of first electrodes, respectively;
a light emitting layer on the plurality of first electrodes; and
a second electrode on the light emitting layer,
wherein each of the plurality of emission areas has a circular shape in a plan view, and
the plurality of emission areas have a same size in the plan view.

2. The display device of claim 1, further comprising a wire grid polarizer on the second electrode.

3. The display device of claim 2, further comprising a lens layer on the wire grid polarizer.

4. The display device of claim 2, further comprising a color filter layer between the second electrode and the wire grid polarizer.

5. The display device of claim 2, further comprising a retardation layer between the second electrode and the wire grid polarizer.

6. The display device of claim 1, wherein each of the plurality of first electrodes has a circular shape in the plan view.

7. The display device of claim 6, wherein the plurality of first electrodes have a same size in the plan view.

8. The display device of claim 1, further comprising a plurality of reflective electrode layers connected to the plurality of first electrodes, respectively.

9. The display device of claim 8, wherein each of the plurality of reflective electrode layers has a circular shape in the plan view.

10. The display device of claim 9, wherein the plurality of reflective electrode layers have a same size in the plan view.

11. The display device of claim 1, wherein the plurality of emission areas are configured to provide light of different colors.

12. An optical device comprising:
a display device; and
an optical path changing member on the display device,
wherein the display device comprises:
a substrate;
a plurality of first electrodes on the substrate;
a pixel defining layer defining a plurality of emission areas disposed to correspond to the plurality of first electrodes, respectively;
a light emitting layer on the plurality of first electrodes; and
a second electrode on the light emitting layer,
wherein each of the plurality of emission areas has a circular shape in a plan view, and
the plurality of emission areas have a same size in the plan view.

13. The optical device of claim 12, further comprising a wire grid polarizer on the second electrode.

14. The optical device of claim 13, further comprising a lens layer on the wire grid polarizer.

15. The optical device of claim 13, further comprising a color filter layer between the second electrode and the wire grid polarizer.

16. The optical device of claim 13, further comprising a retardation layer between the second electrode and the wire grid polarizer.

17. The optical device of claim 12, wherein each of the plurality of first electrodes has a circular shape in the plan view.

18. The optical device of claim 17, wherein the plurality of first electrodes have the same size in the plan view.

19. The optical device of claim 12, further comprising a plurality of reflective electrode layers connected to the plurality of first electrodes, respectively.

20. The optical device of claim 19, wherein each of the plurality of reflective electrode layers has a circular shape in the plan view.

21. The optical device of claim 20, wherein the plurality of reflective electrode layers have a same size in the plan view.

22. The optical device of claim 12, wherein the plurality of emission areas are configured to provide light of different colors.
